(19) United States
(12) Patent Application Publication
(10) Pub. No.: US 2025/0104887 A1
(43) Pub. Date: Mar. 27, 2025

(54) CABLE STRUCTURE

(71) Applicant: WONDERMORE CO., LTD., Taipei (TW)

(72) Inventors: SHIHONG CHEN, Taipei (TW); Szu-Ju CHEN, Taipei (TW)

(21) Appl. No.: 18/475,686

(22) Filed: Sep. 27, 2023

(51) Int. Cl. H01B 11/00; H01B 3/44; H01B 7/00; H05K 9/00

(52) U.S. Cl. CPC H01B 11/002; H01B 7/0009; H05K 9/0098; H01B 3/445

(57) ABSTRACT

The cable structure includes two signal cores/wires arranged adjacent to each other and parallelly along the cable with a designed first spacing, an internal insulation layer surrounding the signal cores/wires and having a dielectric coefficient that forms an impedance value for the signal cores/wires, a metal shielding layer surrounding the internal insulation layer and spaced from the signal cores/wires by a designed second spacing, and an outer covering layer surrounding the metal shielding layer. By adjusting and changing the designed first spacing between two signal cores/wires or the designed second spacing between two signal cores/wires and the metal shielding layer, the impedance value of the cable can be modified and designed to achieve the purpose of stably transmitting signals.

### BACKGROUND OF THE INVENTION

### 1. Field of the Invention

The present invention provides a cable structure, especially a cable structure for adjusting and designing impedance values. By adjusting the designed first spacing between the two signal cores/wires or the designed second spacing between the metal shielding layer and the outer edge of the two signal cores/wires, the impedance value of the cable is adjusted and changed, so as to achieve the purpose of the cable stably transmitting serial differential electronic signals.

### 2. Description of the Related Art

In general, cables used for electronic signal or power transmission have different designs depending on the nature of the transmission. In the case of direct current (DC), the obstruction of current flow by objects are referred to as resistance. All materials have resistance, but the magnitude of resistance varies. Materials with very low resistance are called conductors, such as metals, while materials with extremely high resistance are called insulators, such as wood and plastic. There is Also a type of conductor called a semiconductor, which falls between conductors and insulators, and superconductors are materials with almost zero resistance. However, in the field of alternating current (AC), in addition to resistance, capacitance and inductance also impede the flow of current. This phenomenon is referred to as reaction, which can cause unstable impedance during current transmission, leading to unstable conditions in cable transmission.

Regarding the differential electronic signal application of dual-core cable A, FIG. 4 Prior Art solution; it involves the conductors A1, and with an insulation material body B. The two cables A are arranged in parallel. A grounding wire C is positioned at the cross-intersection space of the two insulation bodies B, and an insulation shielding covering material D is wrapped externally to form a serial dual-core cable A. However, due to the fixed distance of the two conductors A1, that is the thickness of insulation material B, when signal is transmitted through the dual-core cable A, the impedance is increased due to the influence of the insulation material B and the insulation shielding covering material D.

Therefore, it is desirable for inventors to study and to improve the fixed cable configurations, then resolve the impedance issue during signal transmission, as well as the issues affecting the stability of signal transmission in cables.

### SUMMARY OF THE INVENTION

In view of the aforementioned problems and shortcomings, the inventor has collected relevant information, conducted multiple evaluations and considerations, and drawn upon years of experience in the industry. Through continuous creation and modification, the inventor has designed and created this cable structure invention.

The main objective of the present invention is to provide a cable structure comprising two signal cores/wires, an internal insulation layer, a metal shielding layer, and an outer covering layer. The two signal cores/wires are arranged adjacent to each other and parallelly along the cable with a designed first spacing, and they are surrounded by the internal insulation layer. The internal insulation layer has a dielectric coefficient that can provide a stable impedance value for the two signal cores/wires. The metal shielding layer is wrapped around the external surface of the internal insulation layer. There is a designed second spacing between the metal shielding layer and the outer edge of the two signal cores/wires. The outer covering layer is further wrapped around the metal shielding layer. By changing the designed first spacing between the adjacent two signal cores/wires or the designed second spacing between the two signal cores/wires and the metal shielding layer, the impedance value of the cable can be changed and designed to achieve stable transmission of serial differential electronic signals.

Another objective of the present invention is that the diameter (w) of the two signal cores/wires can be 0.254 mm [0.010 inches (10 mil)], and the designed first spacing (d) between the two signal cores/wires can be in the range of 0.305 mm to 0.610 mm or 11 mil to 24 mil. A preferred designed first spacing (d) can be 0.305 mm (or 12 mil).

Yet another objective of the present invention is that the dielectric coefficient (ε), also known as relative permittivity, of the internal insulation layer can be 2.1 F/m. Alternatively, it can vary based on the different materials used, each having its own dielectric coefficient (ε).

Another objective of the present invention is that the metal shielding layer can be made of aluminum thin film, copper thin film, or a woven layer of metal braid wires, manufactured using metal materials or metal alloy materials.

Yet another objective of the present invention is that the internal insulation layer and the outer covering layer can be made of insulating materials such as plastic, rubber, or silicone plastics.

### BRIEF DESCRIPTION OF THE DRAWINGS

FIG. 1 is a side sectional view of the cable structure of the present invention.

FIG. 2 is a side sectional view of a preferred embodiment of the present invention.

FIG. 3 is another side view of the cable structure of the present invention.

FIG. 4 is a sectional side view of a conventional cable.

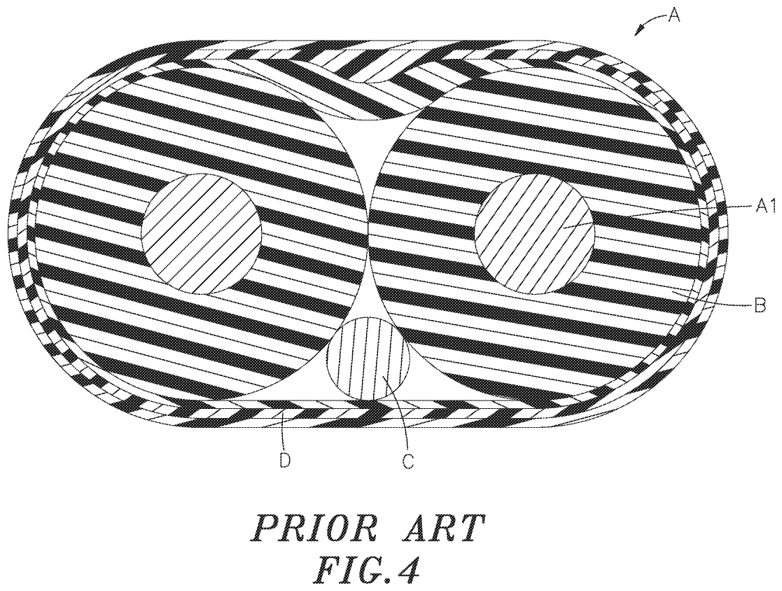

### DETAILED DESCRIPTION OF THE INVENTION

In order to achieve the aforementioned objectives and effects, the technical means, structures, and implementation methods used in the present invention are described in detail below with reference to the preferred embodiments shown in the drawings, enabling a complete understanding.

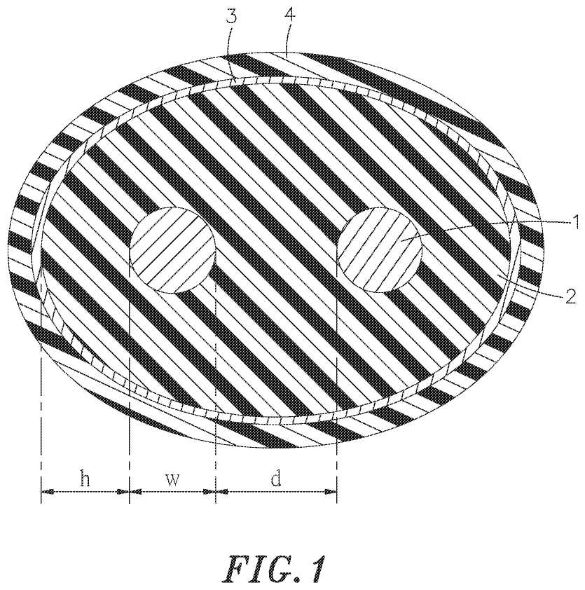

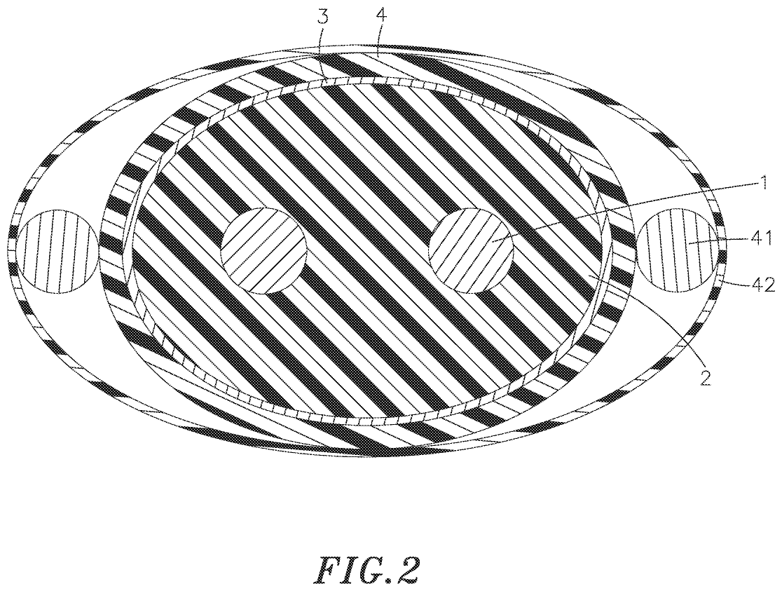

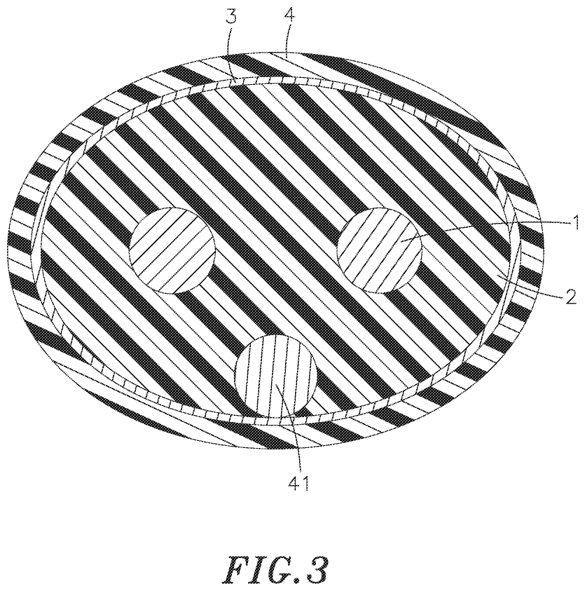

Please refer to FIGS. 1, 2 and 3, which depict a side sectional view of the cable structure of the present invention and a side sectional view of a preferred embodiment, respectively. As shown in the figures, the cable structure of the present invention comprises two signal cores/wires 1, an internal insulation layer 2, a metal shielding layer 3, and an outer covering layer 4. Specifically:

The two signal cores/wires 1 are arranged adjacent to each other and parallelly along the cable with a designed first spacing (d).

The internal insulation layer 2 is wrapped around the outside of the two signal cores/wires 1 and has a dielectric coefficient that provides a stable impedance value for the two signal cores/wires 1.

The metal shielding layer 3 is wrapped around the outside of the internal insulation layer 2, and there is a designed second spacing (h) between the metal shielding layer 3 and the outer edge of the two signal cores/wires 1.

The outer covering layer 4 is wrapped around the outside of the metal shielding layer 3.

The diameter (w) of the aforementioned two signal cores/wires 1 can be 0.254 mm [0.010 inches (10 mil)], and the designed first spacing (d) between the two signal cores/wires 1 can range from 0.305 mm to 0.610 mm or 11 mil to 24 mil. A preferred designed first spacing (d) can be 0.305 mm (or 12 mil).

Furthermore, the designed second spacing (h) between the metal shielding layer 3 and the outer edge of the two signal cores/wires 1 can range from 0.203 mm to 0.356 mm or 8 mil to 14 mil. A preferred designed second spacing (h) can be 0.279 mm (or 11 mil). The metal shielding layer 3 can be made of aluminum thin film, copper thin film, or a woven layer of metal wires, manufactured using various metal materials. It can also provide grounding functionality to eliminate external noise interference on the two signal cores/wires 1 and enhance the relative interpretability of the differential electronic signals on the two signal cores/wires 1.

The internal insulation layer 2 and the outer covering layer 4 mentioned above can be made of insulating materials such as plastics, rubber, or silicone. The dielectric coefficient (ε), also known as relative permittivity, of the internal insulation layer 2 can be 2.1 F/m. Furthermore, the internal insulation layer 2 can have a double focus elliptical or hyperbolic shape to provide a closed enclosure around the outside of the two signal cores/wires 1. The internal insulation layer 2 can be made of the same material (e.g., polytetrafluoroethylene (PTFE), polyethylene (PE), or polystyrene (PS)), where any one of these materials can be used. However, the present invention can use a single coefficient for the dielectric coefficient (ε), which can be 2.1 F/m. This allows the two signal cores/wires 1 to be integrally molded and covered by the internal insulation layer 2, which needs to be selected based on the frequency and transmission speed of the corresponding serial electronic differential signals formed by the two signal cores/wires 1.

Additionally, on the two outer side of the outer covering layer 4, there can be grounding core wires 41 made of metal material. The two grounding core wires 41 can be further covered with a protective layer 42 made of insulating materials such as plastic, rubber, or silicone plastics.

The impedance value (Zd) of the internal insulation layer 2 can be calculated using the following equation:

$$Z d ≅ \frac{174}{\sqrt{ε + 1. 41}} ln ( \frac{5.98 \times h}{0.8 \times ( 2 w )} ) ( 1 - 0.48 exp ( - 0.96 \frac{d}{h} ) ) + C 1$$

In the above equation, Zd represents the impedance value of the two signal cores/wires 1, ε represents the dielectric coefficient of the internal insulation layer 2 (preferably 2.1 F/m), w represents the diameter of the two signal cores/wires 1, h represents the designed second spacing between the metal shielding layer 3 and the outer edge of the two signal cores/wires 1, and d represents the designed first spacing between the two signal cores/wires 1.
C1 is the manufacturing and experience coefficient,
and reference to the differential of parameters—h & d;

$$\frac{d}{d h} ( Zd ) ; \frac{d}{d d} ( Zd ) \\ \frac{d}{d h} ( Z d ) ≅ \frac{174}{\sqrt{ε + 1.41}} \frac{1}{h} ( 1 - 0.48 exp ( - 0.96 \frac{d}{h} ) ) - \frac{174}{\sqrt{ε + 1.41}} \frac{1}{{h}^{2}} ( 1 - 0.48 exp ( - 0.96 \frac{d}{h} ) ) ln ( \frac{5.98 \times h}{0.8 \times ( 2 w )} ) \\ \frac{d}{d d} ( Z d ) ≅ \frac{174}{\sqrt{ε + 1.41}} ln ( \frac{5.98 \times h}{0.8 \times ( 2 w )} ) \cdot \frac{0.46}{h} ( exp ( - 0.96 \frac{d}{h} ) )$$

The internal insulation layer 2 can be made of the same material (e.g., polytetrafluoroethylene (PTFE) with dielectric coefficient (ε): 2.1, polyethylene (PE) with dielectric coefficient (ε): 2.2 to 2.4, or polystyrene (PS) with dielectric coefficient (ε): 2.4 to 2.6, where any one of these insulation materials can be used). However, the present invention can use a single dielectric coefficient (ε), which can be 2.1 F/m. Alternatively, the dielectric coefficient (ε) can vary based on the different materials used, each having its own dielectric coefficient, allowing for variation in impedance values.

By using the above equation, the impedance design for achieving stable impedance values (Zd) of the two signal cores/wires 1 can be calculated.

First Preferred Embodiment: The diameter (w) of the two signal cores/wires 1, with a wire gauge (AWG) of 30, can be 0.010 inches (10 mil or 0.254 mm). The designed second spacing (h) between the metal shielding layer 3 and the outer edge of the two signal cores/wires 1 is also 0.010 inches (10 mil or 0.254 mm). The impedance value (Zd) is 100 ohms with a tolerance of ±6%. The dielectric coefficient (ε) of the internal insulation layer 2 is 2.1 F/m. By changing the designed first spacing (d) between the two signal cores/wires 1, it can be set between 0.012 inches to 0.023 inches (or 0.305 mm to 0.584 mm), with a preferred value of 0.016 inches (or 0.406 mm), for the design of the designed first spacing (d).

Second Preferred Embodiment: The diameter (w) of the two signal cores/wires 1, with a wire gauge (AWG) of 30, can be 0.010 inches (10 mil or 0.254 mm). The designed first spacing (d) between the two signal cores/wires 1 is 0.012 inches (or 0.305 mm). The impedance value (Zd) is 100 ohms with a tolerance of ±6%. The dielectric coefficient (ε) of the internal insulation layer 2 is 2.1 F/m. By changing the designed second spacing (h) between the metal shielding layer 3 and the outer edge of the two signal cores/wires 1, it can be set between 0.010 inches to 0.012 inches (or 0.254 mm to 0.305 mm), with a preferred value of 0.011 inches (or 0.279 mm), for the design of the designed second spacing (h).

Third Preferred Embodiment: The diameter (w) of the two signal cores/wires 1, with a wire gauge (AWG) of 30, can be 0.010 inches (10 mil or 0.254 mm). The designed second spacing (h) between the metal shielding layer 3 and the outer edge of the two signal cores/wires 1 is also 0.010 inches (10 mil or 0.254 mm). The impedance value (Zd) is 85 ohms with a tolerance of ±6%. The dielectric coefficient (ε) of the internal insulation layer 2 is 2.1 F/m. By changing the designed first spacing (d) between the two signal cores/wires 1, it can be set between 0.008 inches to 0.013 inches (or 0.203 mm to 0.330 mm), with a preferred value of 0.010 inches (or 0.254 mm), for the design of the designed first spacing (d).

Fourth Preferred Embodiment: The diameter (w) of the two signal cores/wires 1, with a wire gauge (AWG) of 30, can be 0.010 inches (10 mil or 0.254 mm). The designed first spacing (d) between the two signal cores/wires 1 is 0.010 inches (or 0.254 mm). The impedance value (Zd) is 85 ohms with a tolerance of ±6%. The dielectric coefficient (ε) of the internal insulation layer 2 is 2.1 F/m. By changing the designed second spacing (h) between the metal shielding layer 3 and the outer edge of the two signal cores/wires 1, it can be set between 0.008 inches to 0.010 inches (or 0.203 mm to 0.254 mm), with a preferred value of 0.009 inches (or 0.229 mm), for the design of the designed second spacing (h).

Furthermore, the outer surface of the outer covering layer 4 is smooth. Based on the shape of the internal insulation layer 2 and the metal shielding layer 3 (which can have geometric variations), a smooth and complete encapsulation can be formed, such as an elliptical or hyperbolic with a bifocal shape. This closed encapsulation maintains the integrity of the two signal cores/wires 1, preventing distortion or deformation, and provides complete transmission of high-speed, high-frequency serial differential electronic signals within the internal insulation layer 2 and the metal shielding layer 3. It also helps eliminate noise interference and increase relative interpretability. Alternatively, the two signal cores/wires 1 can be used for applications involving high-speed, low-frequency signals or larger wavelengths, providing benefits such as increased; VSWR (Voltage standing wave ratio); return loss (1/2λ) for serial differential electronic signals, eliminating noise interference, and enhancing relative interpretability accuracy.

The above description provides preferred embodiments of the present invention, but it does not limit the scope of the patent. Therefore, any simple modifications or equivalent structural changes made based on the content of the present invention's specification and drawings should be included within the scope of the patent.

In summary, the cable structure described in the present invention is highly practical and effective in achieving its purpose. In accordance with the requirements for patent applications, the present invention is submitted for review and approval, with the hope that the competent authorities will grant the patent as soon as possible to protect the hard work and research efforts of the inventors. If the reviewing committee has any doubts or questions, please feel free to contact us. The inventors will be more than willing to cooperate and provide further clarification.

What is claimed is:

1. A cable structure, comprising: two signal cores/wires, an internal insulation layer, a metal shielding layer, and an outer covering layer, wherein;
said two signal cores/wires are arranged adjacent to each other and parallelly along a cable with a designed first spacing;
said internal insulation layer is wrapped around an outside of said two signal cores/wires and has a dielectric coefficient that forms an impedance value for said two signal cores/wires;
said metal shielding layer is wrapped around an outside of said internal insulation layer, and there is a designed second spacing between said metal shielding layer and outer edge of said two signal cores/wires;
said outer covering layer is wrapped around an outside of said metal shielding layer.

2. The cable structure as claimed in claim 1, wherein said dielectric coefficient (relative permittivity) of said internal insulation layer property is an insulating material, for example: Teflon (PTFE, the dielectric coefficient is 2.1 F/m); said internal insulation layer and said metal shielding layer form a bifocal elliptical or hyperbolic shape, forming a closed single insulating cavity that is wrapped an outside said two signal cores/wires.

3. The cable structure as claimed in claim 1, wherein diameter (w) of said two signal cores/wires is 0.254 mm [0.010 inches (10 mil)], said designed second spacing (h) is set to 0.010 inches (10 mil or 0.254 mm), said designed first spacing (d) between said two signal cores/wires is designed between 0.305 mm and 0.610 mm or 11 mil and 24 mil, and preferably said designed first spacing (d) is 0.406 mm (or 16 mil), so that the impedance value (Zd) of the cable structure is: 100 ohm.

4. The cable structure as claimed in claim 1, wherein diameter of said two signal cores/wires is 0.254 mm [0.010 inches (10 mil)], said designed first spacing (d) between said two signal cores/wires is set to 0.305 mm [0.012 inches (12 mil)], said designed second spacing (h) between said metal shielding layer and the outside of said two signal cores/wires is designed between 0.203 mm and 0.356 mm or between 8 mil and 14 mil, and preferably said designed second spacing (h) is 0.279 mm (11 mil), so that the impedance value of the cable structure is: 100 ohm.

5. The cable structure as claimed in claim 1, wherein said metal shielding layer is selectively made of aluminum film, copper film, or metal wire braid.

6. The cable structure as claimed in claim 1, wherein said internal insulation layer and said outer covering layer are made of insulation materials selected from group of plastics, rubber and silicone.

7. The cable structure as claimed in claim 1, further comprising two opposing grounding core wires arranged an outside said outer covering layer, and a protective layer of insulating material wrapped around said grounding core wires.

8. The cable structure as claimed in claim 1, wherein said impedance value (Zd) is calculated using an equation of:
$$Z d ≅ \frac{174}{\sqrt{ε + 1.41}} ln ( \frac{5.98 \times h}{0.8 \times ( 2 w )} ) ( 1 - 0.48 exp ( - 0.96 \frac{d}{h} ) ) + C 1$$
where said equation, (Zd) represents the impedance value of said two signal cores/wires, (ε) represents the dielectric coefficient of said internal insulation layer, (w) represents the diameter of said two signal cores/wires, (h) represents said designed second spacing between said metal shielding layer and said two signal cores/wires, and (d) represents said designed first spacing between said two signal cores/wires.
C1 is the manufacturing and experience coefficient,
and reference to the differential of parameters—h & d;
$$\frac{d}{d h} ( Zd ) ; \frac{d}{d d} ( Zd ) \\ \frac{d}{d h} ( Z d ) ≅ \frac{174}{\sqrt{ε + 1.41}} \frac{1}{h} ( 1 - 0.48 exp ( - 0.96 \frac{d}{h} ) ) - \frac{174}{\sqrt{ε + 1.41}} \frac{1}{{h}^{2}} ( 1 - 0.48 exp ( - 0.96 \frac{d}{h} ) ) ln ( \frac{5.98 \times h}{0.8 \times ( 2 w )} ) \\ \frac{d}{d d} ( Z d ) ≅ \frac{174}{\sqrt{ε + 1.41}} ln ( \frac{5.98 \times h}{0.8 \times ( 2 w )} ) \cdot \frac{0.46}{h} ( exp ( - 0.96 \frac{d}{h} ) )$$

9. The cable structure as claimed in claim 1, wherein said internal insulation layer is made of one of materials of polytetrafluoroethylene (PTFE), polyethylene (PE) and polystyrene (PS), with a single evaluable dielectric coefficient [(ε), or relative permittivity], for example, PTFE: 2.1 F/m, or according to the different dielectric coefficients (E) of different materials used.

10. The cable structure as claimed in claim 2, wherein said two signal cores/wires are used for high-speed low-frequency signals (with larger wavelengths) in differential electrical signaling, providing, (VSWR, Voltage standing wave ratio), a standing wave ratio gain (1/2λ) of a reflected bouncing wave.
